(19) United States
(12) Patent Application Publication
(10) Pub. No.: US 2024/0258449 A1
(43) Pub. Date: Aug. 1, 2024

(54) MULTI-JUNCTION SOLAR CELL

(71) Applicant: MEYER BURGER (GERMANY) GMBH, Hohenstein-Ernstthal (DE)

(72) Inventor: Hermann-Josef NONNENMACHER, Leipzig (DE)

(73) Assignee: MEYER BURGER (GERMANY) GMBH, Hohenstein-Ernstthal (DE)

(21) Appl. No.: 18/560,876

(22) PCT Filed: May 17, 2022
(86) PCT No.: PCT/DE2022/100367

§ 371 Date: Nov. 14, 2023

(30) Foreign Application Priority Data
May 21, 2021 (DE) 10 2021 113 294.0

(51) Int. Cl. H01L 31/05; H01L 31/028; H01L 31/043; H01L 31/0747

(52) U.S. Cl. CPC H01L 31/05; H01L 31/028; H01L 31/043; H01L 31/0747

(57) ABSTRACT

The invention relates to a multi-junction solar cell comprising at least two sub-cells based on silicon and at least one material other than silicon, wherein a first sub-cell is designed to use photons in a spectral region of a shorter wavelength than a spectral region of a longer wavelength of a second sub-cell, the second sub-cell being based on silicon and the first sub-cell being based on a material which has a larger band gap than silicon, wherein the first sub-cell and the second sub-cell are designed as a monolithic unit consisting of a layer stack, and wherein the first sub-cell and the second sub-cell are electrically connected to one another in series by means of a tunnel diode, such that the tandem solar cell is equipped with two terminals, wherein the tunnel diode has a tunnel diode n layer and a tunnel diode p layer. The problem addressed is that of proposing a multi-junction solar cell of simple construction. The problem is solved by multi-junction solar cells in which the tunnel diode n layer and/or the tunnel diode p layer is/are silicon-based layer(s).

The present invention relates to a multi-junction solar cell comprising at least two subcells based on silicon and at least one material other than silicon, wherein a first subcell is configured to use photons in a spectral range of shorter wavelength than a spectral range of longer wavelength of a second subcell, in that the second subcell is based on silicon and the first subcell is based on a material with a larger band gap than silicon, wherein the first subcell and the second subcell are in the form of a monolithic unit consisting of a layer stack, and wherein the first subcell and the second subcell are electrically connected to one another in series by means of a tunnel diode, so that the tandem solar cell is provided with two terminals, wherein the tunnel diode has a tunnel diode n-layer and a tunnel diode p-layer.

Over the past two decades, the global solar cell industry has, on the one hand, continuously improved the performance of solar cells and, on the other hand, has reduced the manufacturing costs of solar cells and the electrical energy they generate. In recent years, multi- and monocrystalline silicon solar cells have dominated the market for solar cells and solar modules, wherein crystalline silicon solar cells are generally single-junction solar cells with only one pn-junction. The efficiency of solar cells manufactured in large volumes could and can be improved compared to the respective predecessor technology by PERC, passivated contact or PACO and HJT technologies. However, the production technologies of single-junction silicon solar cells have already been improved to such an extent that the potential for further future improvement has already been largely exhausted. The efficiency of single-junction silicon solar cells is gradually reaching its physical limits.

Tandem solar cells or other multi-junction solar cells, in which two or more subcells with different spectral sensitivity together form the multi-junction solar cell, can theoretically and practically achieve greater efficiencies than single-junction solar cells. Commercially available multi-junction solar cells made from III-V-semiconductors achieve record efficiencies. Such solar cells are used successfully in extraterrestrial applications. However, for terrestrial applications III-V solar cells are not competitive with crystalline silicon solar cells, due to high manufacturing costs and ultimately high electricity generation costs. In the first decade of the 21st century, silicon thin-film solar cells and solar modules were produced, consisting of various amorphous and microcrystalline subcells, as described for example in EP 2 599 127 B1. Despite low manufacturing costs, however, these thin-film manufacturing technologies were displaced by manufacturing technologies based on crystalline solar wafers because the module efficiencies achieved were too low.

Tandem solar cells made from two different materials, e.g. which combine a conventional silicon solar cell and a perovskite thin-film solar cell with a light absorber layer made from a perovskite material, and multi-junction solar cells, which have at least one other perovskite layer, are currently regarded by experts as promising candidates for future mainstream solar cells. In recent years, research laboratories have been able to achieve improvements in the efficiency and stability of silicon-perovskite tandem solar cells. However, further technical improvements are required for the successful industrial production of silicon-perovskite tandem solar cells. Leading laboratory demonstrator tandem solar cells, such as those known from GB 2559800 B, generally have a complex structure with a plurality of layers and are thus expensive to produce. However, low manufacturing costs are required for this to be economically significant.

The objective of the present invention is therefore to propose simply constructed multi-junction solar cells.

The objective is achieved by multi-junction solar cells in which the tunnel diode-n-layer and/or the tunnel diode p-layer are silicon-based layers. In monolithic tandem solar cells and multi-junction solar cells with more than two subcells, the subcells are connected in series in the same direction. In equivalent circuit diagrams, individual solar cells and subcells of multi-junction solar cells can be represented as diodes, which are all connected in forward direction in the series connection of the multi-junction solar cells. Accordingly, the p- and n-type layers in the subcells are arranged respectively in the same sequence. This means that in order to connect two subcells an n- and p-type layer have to be connected in a sequence which is the reverse of the layer sequence in the individual subcells. If the converging n-type layer on one subcell and a p-type layer on the other subcell form a (connecting) diode, then this diode would be connected in reverse direction. As a current flow is still required, the conductive connection between the n- and p-type layers is in the form of a tunnel diode, which enables the required current flow despite the existing layer sequence. Sometimes the layer of one conductivity type (n or p) that borders the layer of the other conductivity type (p or n) of the subcell is also referred to as a recombination layer, because here the electron flowing from the n-type layer of one subcell and the holes flowing from the p-type layer of the other subcell recombine with one another. Various, easy-to-produce and thus inexpensive silicon-based recombination layers are known from Si thin-film solar cells. Similar recombination layers can be used according to the invention in tandem and multi-junction solar cells which consist of at least two different materials, for example in silicon-perovskite tandem cells. The properties of the recombination layers can be optimized for optimum function. The tunnel junction can be formed at the boundary of a subcell and a recombination layer or between two tunnel diode layers, which are arranged in the multi-junction solar cell in addition to the layers belonging to the subcells.

If for example the outermost layer of an Si subcell is an n-type Si layer, then the tunnel junction can be formed between this n-type Si layer and a p-type silicon-based recombination layer. In this example the n-type Si layer is used as a tunnel diode n-layer and the p-type silicon-based recombination layer is used as a tunnel diode p-layer. In another example, the adjacent layer of the Si subcell is p-type and the recombination layer is n-type. In a further example, the multi-junction solar cell between the subcells to be connected has two inversely doped silicon-based layers, one of which is the tunnel diode n-layer and the other of which is tunnel diode p-layer. In further examples, the tunnel diode is formed between an n-type silicon-based recombination layer and a p-type layer of the first subcell or between a p-type silicon-based recombination layer and an n-type layer of the first subcell.

The silicon-based layer can be a more or less dense silicon layer, it can include other components in addition to silicon, in particular hydrogen and dopants. The silicon-based layer can also be silicon alloy, for example comprising oxygen (O), carbon (C) or nitrogen (N). The attribute “silicon-based” means that silicon is an essential component of the layer or that the atomic fraction of silicon is greater than 30%. In many exemplary embodiments the silicon content is much greater than 50%.

At least one of the tunnel diode n-layer and/or the tunnel diode p-layer of the multi-junction solar cell according to the invention can be a doped alloy of silicon and at least one further alloy component M with the summation formula SiMₓ-layer (8, 9), wherein M represents at least one of the elements O, C or N. The alloy can also be a ternary or a quaternary alloy which contains two or three of the indicated elements. The use of such silicon alloy layers has already been proposed in the aforementioned prior art for silicon thin-film layer multi-junction solar cells. Since the development of solar cells has gone in different directions in the meantime, earlier ideas from the field of Si thin-film solar technology have been forgotten so that Si thin-film solar technology can no longer be regarded as an adjacent field to the Si perovskite tandem or multi-junction solar cells being developed today. The class of SiMₓ alloy layers includes very different materials, for example layers, in which conductive Si grains are embedded in less conductive SiOₓN_{y} or in an SiNx matrix. Other materials can have a two-phase structure consisting of a matrix and highly conductive SiC grains embedded therein. However, the formula SiMₓ also includes single-phase semiconductive layers that contain silicon carbide bonds.

In one embodiment of the multi-junction solar cell according to the invention, the tunnel diode n-layer is a highly n-doped Si surface-higher doping layer of the second subcell and the tunnel diode p-layer is a doped SiMₓ layer with x<1, wherein the SiMₓ-layer is inhomogeneous and consists of a silicon alloy matrix and silicon inclusions embedded therein. Such a multi-junction solar cell has a particularly simple structure because the tunnel diode does not consist entirely of additional deposited layers. Instead, the surface-higher doping layer of silicon, already present from the production of the second subcell, is also used as a tunnel diode n-layer, so that the tunnel diode is already produced after the deposition of a layer, namely the SiMₓ-layer. SiMₓ layers can be in the form of recombination layers with a high normal conductivity and a lower lateral conductivity. However, the SiMₓ layer can also have the same conductivities in lateral and normal directions. At the discretion of a person skilled in the art, the SiMₓ can be substituted by alternative Si-based layer materials. In a multi-junction solar cell according to the invention, both the tunnel diode n-layer and the tunnel diode p-layer can also be a doped SiMₓ layer. The tunnel diode can therefore also be produced from two oppositely doped silicon alloy layers SiMₓ layers. For activating the dopants and/or for producing a microcrystalline layer structure the layers can be post-treated accordingly. If the Si subcell is a temperature-sensitive heterojunction solar cell, then the post-treatment of deposited layers can be carried out using a surface-active method, for example a flashlight post-treatment. With oxygen and/or nitrogen doping of the silicon in the SiMₓ-layers, the optical losses in the coupling area of the subcells can be partially reduced compared to other coupling layers.

The SiMₓ-layer in the multi-junction solar cell according to the invention can be gradient layer, wherein the electrical conductivity of the gradient layer at the boundary of the pn-junction of the tunnel diode is greater than at the other boundary of the SiMₓ-layer, and wherein the refractive index of the gradient layer increases in a direction from the first subcell to the second subcell. The alloy material content, e.g. the oxygen content in an SiOₓ-layer, can therefore be a function of the layer thickness. With a gradient layer, unlike with layers that are homogeneous over the layer thickness, various objectives can be achieved by setting gradient parameters, for example on the one hand the formation of a tunnel junction at a boundary can be achieved and on the other hand a refractive index that is only slightly higher than that of the adjacent layer in the perovskite subcell can be set at the boundary to the perovskite subcell so that reflection losses are minimized due to the good optical adaptation.

At least one of the tunnel diode-n-layer and the tunnel diode-p-layer of the multi-junction solar cell according to the invention can be a doped amorphous Si layer. Amorphous layers can be produced with good structural properties (compliant, smooth deposition) and sufficiently good electrical properties. Optical losses can be minimized by thin layer thicknesses, wherein thin layer thicknesses are also associated with low manufacturing costs. An amorphous Si layer can form the tunnel diode as a recombination layer in interaction with an adjacent layer of a subcell. At least one of the tunnel diode n-layer and the tunnel diode p-layer can also be a doped nano- or microcrystalline Si layer. The nano- or microcrystalline morphology can be produced either during the layer deposition by suitable process parameters or after the deposition in a suitable post-treatment. The attributes nanocrystalline and microcrystalline refer to crystallite dimensions in the nanometer range or micrometer range. Crystallite dimensions are often similar in size in different spatial directions. Sometimes the largest crystallite dimension is in the micrometer range, while other crystallite dimensions are smaller than 1000 nm, i.e. in the nanometer range. This relates in particular to the layer thickness and the resulting normal dimension.

The second subcell of the multi-junction solar cell according to the invention can be a silicon heterojunction solar cell, in which the pn-junction is formed between a crystalline silicon wafer and at least one layer of another material deposited thereon. Heterojunction solar cells are the most efficient Si single-junction solar cells available. They are therefore a good prerequisite for high overall efficiencies of the multi-junction solar cells based thereon with one or more than one broader-band subcell, e.g. based on a perovskite material. The silicon subcell can have a proven structure including intrinsic passivation layers and surface textures. In addition to the crystalline silicon wafer, at least one amorphous silicon layer can be involved in the formation of the silicon heterojunction solar cell. To produce the silicon heterojunction solar cells, an n-crystalline solar wafer can be coated on one side with an intrinsic (i) aSi layer and a p-doped aSi layer to form the emitter of the solar cell. On the other side an intrinsic aSi layer and a surface field layer n-doped higher than the substrate are deposited so that a potential gradient is present over the entire Si-HJT cell, which promotes the conduction of the charge carriers separated by the photoelectric effect to the contacts or the terminals of the solar cell or the solar subcell. The i and the n-aSi layer can also be combined as a gradient layer. There are many different types of Si heterojunction solar cells. The substrate can be n- or p-doped, the emitter can be arranged on the side facing the sun or on the other side (rear side). The doped semiconductor layers can be amorphous, nano- or microcrystalline. The semiconductor material can be Si or an alloy, e.g. SiCₓ or SiOₓ. All of these different solar cell types can also be the Si subcell of a multi-junction solar cell according to the invention. In addition to the crystalline silicon wafer also at least one nano- or microcrystalline silicon layer can be involved in the formation of the silicon heterojunction solar cell. Nano- and microcrystalline layers can have advantages over amorphous layers, for example higher conductivities. These advantages can be specifically utilized when determining an optimum layer sequence in the silicon heterojunction solar cell.

In one embodiment, the second subcell of the multi-junction solar cell according to the invention, namely an Si heterojunction solar cell, has an n-doped substrate, an intrinsic amorphous silicon layer and a p-doped amorphous silicon layer on its side facing away from the first subcell and a n-doped gradient layer with lower doping at the boundary to the silicon wafer on its side facing the first subcell, wherein the multi-junction solar cell has an n-SiMₓ and a p-SiMₓ-layer in the specified order and either a p-type transition metal oxide layer or directly a hole transport layer of the first subcell. This solar cell has a very simple structure and is made from easily available inexpensive materials. In a simple example between the two part solar cells only two SiOx-layers forming the tunnel diode are arranged. In other embodiments in addition a transition metal oxide layer is arranged between the p-SiMx-layer and the hole transport layer of the first subcell. Transition metal oxide layers have been tried and tested as boundary layers to hole transport layers.

In some multi-junction solar cells according to the invention, the second subcell has an n-doped substrate, an intrinsic amorphous silicon layer and a p-doped amorphous silicon layer on its side facing away from the first subcell and at least one n-Si-layer on its side facing the first subcell, wherein the multi-junction solar cell has an amorphous p-Si layer on the n-Si layer and thereon either a p-type transition metal oxide layer or directly a hole transport layer of the first subcell.

In other embodiments of multi-junction solar cells according to the invention, the second subcell has an n-doped substrate, an intrinsic silicon layer and a p-doped silicon layer on its side facing away from the first subcell and at least one nano or microcrystalline n-Si layer on its side facing the first subcell, wherein the multi-junction solar cell on the nano or microcrystalline n-Si layer has a nano- or microcrystalline p-Si layer and thereon either a p-type transition metal oxide layer or directly a hole transport layer of the first sub-cell. At the boundary to the silicon, intrinsic (i) Si layers can be provided. The i-Si-layer can also be a layer within the (n)-Si-layer which has been produced in a deposition step without doping gas intake. In contrast to the embodiments described in the previous paragraph, at least one of the aforementioned Si layers has a nano- or microcrystalline structure instead of an amorphous structure. Nano- and microcrystalline layers have the advantage that high electrical conductivities can be adjusted therein.

The invention also comprises solar modules produced from multi-junction solar cells according to the invention.

For the functioning of multi-junction solar cells according to the invention, a targeted, carefully executed manufacturing method is required. In this respect the present invention also comprises a manufacturing method in which a silicon-based tunnel diode n-layer and/or a silicon-based tunnel diode-p-layer is deposited in corresponding method steps.

By using their expertise persons skilled in the art in the field of the invention can derive further embodiments of the invention which are also included in the scope of protection of the claims, without these embodiments being described here specifically.

The present invention will be explained further in the following with reference to exemplary embodiments depicted in the Figures, wherein

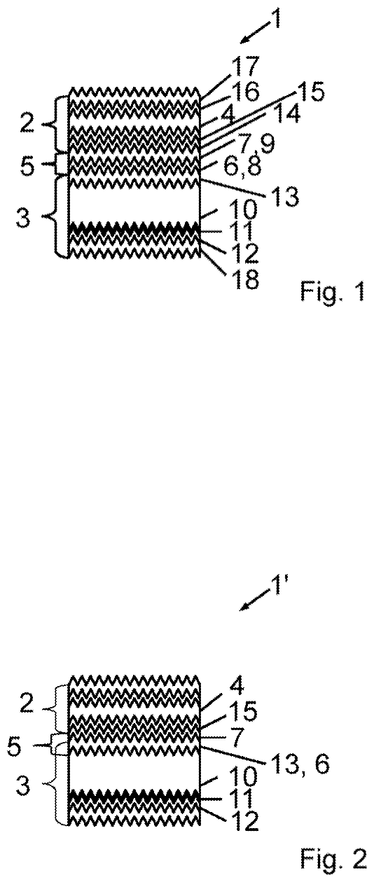

FIG. 1 shows a first exemplary embodiment of a multi-junction solar cell 1 according to the invention and

FIG. 2 shows a second exemplary embodiment of a multi-junction solar cell 1 according to the invention.

FIG. 1 depicts the structure of an exemplary embodiment of a semi-finished product of a multi-junction solar cell 1 according to the invention. In an approximate view the multi-junction solar cell consists of a first subcell 2, a second subcell 3 and a tunnel diode 5 connecting the subcells 2, 3. The multi-junction solar cell is produced by a plurality of coating processes of a crystalline silicon solar wafer 10. As is known to those skilled in the art in the field of the invention, the properties of deposited layers depend strongly on the deposition methods used and the general conditions before and after deposition, so that there is a close relationship between the multi-junction solar cell 1 according to the invention and the manufacturing method according to the invention. In the exemplary embodiment shown the multi-junction solar cell 1 is a tandem solar cell, whose front side facing the sun is shown at the top. When solar radiation with its known spectrum shines into the multi-junction solar cell from the front, a short-wave, in particular visible, spectral component is absorbed by the first subcell and converted into a photocurrent, and a longer-wave, in particular infrared, spectral range is transmitted to the second subcell and converted there into a photocurrent. The photocurrents generated by the two or more generally all subcells are designed to be the same size in multi-junction solar cells equipped with only two terminals at low cost in order to maximize the output and efficiency of the multi-junction solar cell. The second subcell 3 in the presented exemplary embodiment is a silicon heterojunction solar cell based on an n-doped wafer. For high-performance solar cells n-doped starting wafers are currently preferred, but in principle p-doped solar wafers can also be used as the starting material for multi-junction solar cells. The silicon wafer is textured on both sides here because the best efficiencies are achieved with textured solar cells. In the shown exemplary embodiment, an intrinsic (i) amorphous silicon layer (aSi) 11 and then a p-doped aSi layer 12 are arranged on the rear side of the solar wafer 10 which forms the emitter of the Si heterojunction subcell 3. In other exemplary embodiments, not shown, the emitter is located on the front side. The a-Si layers 11, 12, 13 are generally produced by CVD processes using hydrogen-containing precursors, wherein the hydrogen is partially incorporated into the layers. Therefore, the aSi layers are actually hydrogenised aSi layers (aSi:H). This detail is well known to persons skilled in the art so that there is no need to refer to it here. On the front side, instead of an i-n aSi layer pair an n-type aSi gradient layer 13 is provided which is doped more weakly at the boundary to the silicon wafer 10 than at the opposite boundary. The system used to produce the n-type aSi gradient layer is simpler in design because only one deposition chamber (instead of two separate chambers for i and n) is required. Towards the bottom, the shown semifinished product of a multi-junction solar cell 1 is terminated by a transparent conductive layer (TCO) 18, wherein the TCO 18 is used, on the one hand, as a first part of an electric terminal electrode and, on the other hand, as an anti-reflective layer. The electric terminal in the solar module produced from the multi-junction solar cell 1 also comprises further components, not shown here, namely screen-printed contact fingers and wire-shaped collector lines connected thereto. In other exemplary embodiments other electrodes are used, for example with screen-printed bus lines or large-area metal surfaces. These and other components of solar modules are known from the prior art and are omitted from the drawing here for the sake of clarity.

In the shown exemplary embodiment, the first subcell 2 consists of the perovskite absorber layer 4 of an organic hole transport layer 15 and a metal junction oxide layer 14 on the underside of this first subcell 2 and an electron transport layer 16 and a TCO layer 17 on the front side of the first subcell 2. Further electrode components are omitted from FIG. 1 for the sake of clarity as is the case on the rear side of the multi-junction solar cell 1.

The electrical and optical connection of the first subcell 2 and the second subcell 3 is performed by means of a tunnel diode 5 in the exemplary embodiment presented here. The n-type SiOₓ-layer 8 has the function of the tunnel diode n-layer 6 and the p-type SiOₓ-layer 9 has the function of the tunnel diode p-layer 7. The SiOₓ-layers 8, 9 are configured to form a tunnel junction between the two SiOₓ-layers 8, 9.

FIG. 2 shows a second exemplary embodiment of a multi-junction solar cell 1′ according to the invention, which has an even simpler structure than the multi-junction solar cell 1 shown in FIG. 1. Apart from the differences described below, this second exemplary embodiment also has similarities with the first exemplary embodiment. To avoid repetition, reference is therefore made to the explanations for FIG. 1. Here only a single layer is arranged between the first subcell 2 and the second subcell 3, namely the p-doped aSi layer, which functions as the tunnel diode p-layer 7 or recombination layer. The function of the tunnel diode-n-layer is not assumed here by a separately deposited layer, but by the n-type aSi gradient layer 13 of the second subcell 3 as an additional function. This results in a particularly simple structure of the multi-junction solar cell 1′.

Further, not explicitly presented embodiments result from the present disclosure and relevant expertise in the field of the invention.

### REFERENCE NUMERALS

1, 1′ multi-junction solar cell
2 first subcell
3 second subcell
4 perovskite absorber layer
5 tunnel diode
6 tunnel diode n-layer
7 tunnel diode p-layer
8 n-type SiOₓ layer
9 p-type SiOₓ layer
10 crystalline silicon wafer (n-type)
11 i-aSi
12 p-aSi
13 n-aSi gradient layer
14 transition metal oxide layer
15 hole transport layer
16 electron transport layer
17 front TCO anti-reflection and contact layer
18 rear TCO anti-reflection and contact layer

1-15. (canceled)

16. Multi-junction solar cell comprising at least two subcells based on silicon and a material other than silicon, wherein a first subcell is configured for using photons in a spectral range of shorter wavelength than a second subcell with a spectral range of longer wavelength, in that the second subcell is based on silicon and the first subcell is made from a material with a larger band gap than silicon, wherein the first subcell and the second subcell are configured as a monolithic unit consisting of a layer stack, and wherein the first subcell and the second subcell are connected to one another electrically in series by means of a tunnel diode, so that the tandem solar cell is provided with two terminals, wherein the tunnel diode has a tunnel diode n-layer and a tunnel diode p-layer wherein the tunnel diode n-layer and/or the tunnel diode p-layer is a silicon-based layer.

17. Multi-junction solar cell according to claim 16, wherein at least one of the tunnel diode-n-layer and/or the tunnel diode-p-layer is a doped alloy of silicon and at least one further alloy component M with the summation formula SiMₓ, wherein M represents at least one of the elements O, C or N.

18. Multi-junction solar cell according to claim 17, wherein the tunnel diode n-layer is a highly n-doped Si surface higher doping layer of the second subcell and the tunnel diode p-layer is a doped SiMₓ-layer with x<1, wherein the SiMₓ-layer is inhomogeneous and consists of a silicon alloy matrix and silicon inclusions embedded therein.

19. Multi-junction solar cell according to claim 17, wherein both the tunnel diode n-layer and the tunnel diode p-layer is a doped SiMₓ-layer.

20. Multi-junction solar cell according to claim 17, wherein the SiMₓ-layer is a gradient layer, wherein the electrical conductivity of the gradient layer at the boundary of the pn-junction of the tunnel diode is greater than at the other boundary of the SiMₓ-layer and wherein the refractive index of the gradient layer increases in a direction from the first subcell to the second subcell.

21. Multi-junction solar cell according to claim 16, wherein at least one of the tunnel diode n-layer and the tunnel diode p-layer is a doped amorphous Si layer.

22. Multi-junction solar cell according to claim 16, wherein at least one of the tunnel diode n-layer and the tunnel diode p-layer is a doped nano- or microcrystalline Si layer.

23. Multi-junction solar cell according to claim 16, wherein the second subcell is a silicon heterojunction solar cell, in which the pn-junction is between a crystalline silicon wafer and at least one layer of another material deposited thereon.

24. Multi-junction solar cell according to claim 23, wherein at least one amorphous silicon layer is involved in the formation of the silicon heterojunction solar cell in addition to the crystalline silicon wafer.

25. Multi-junction solar cell according to claim 23, wherein at least one nano- or microcrystalline silicon layer is involved in the formation of the silicon heterojunction solar cell in addition to the crystalline silicon wafer.

26. Multi-junction solar cell according to claim 24, wherein the second subcell has an n-doped substrate, an intrinsic silicon layer and a p-doped silicon layer on its side facing away from the first subcell and an n-doped gradient layer with lower doping at the boundary to the silicon wafer on its side facing the first subcell, wherein the multi-junction solar cell has thereon, in the indicated sequence, an n-SiMₓ and a p-SiMₓ layer and thereon either a p-type transition metal oxide layer or directly a hole transport layer of the first sub-cell.

27. Multi-junction solar cell according to claim 24, wherein the second subcell has an n-doped substrate, an intrinsic amorphous silicon layer and a p-doped amorphous silicon layer on its side facing away from the first subcell and at least one n-Si-layer on its side facing the first subcell, wherein the multi-junction solar cell on the n-Si-layer has an amorphous p-Si-layer and either a p-type transition metal oxide layer or directly a hole transport layer of the first subcell.

28. Multi-junction solar cell according to claim 25, wherein the second subcell has an n-doped substrate, an intrinsic silicon layer and a p-doped silicon layer on its side facing away from the first subcell and at least one nano- or microcrystalline n-Si-layer on its side facing the first subcell, wherein the multi-junction solar cell has on the nano- or microcrystalline n-Si-layer a nano- or microcrystalline p-Si-layer and thereon either a p-type transition metal oxide layer or directly a hole transport layer of the first subcell.

29. Multi-junction solar cell according to claim 16, wherein the multi-junction solar cell has a silicon wafer that is textured on both sides.

30. Method for producing multi-junction solar cells according to claim 16, wherein in the manufacturing method a silicon-based tunnel diode n-layer and/or a tunnel diode p-layer is deposited.
